(19) United States
(12) Patent Application Publication
(10) Pub. No.: US 2005/0284516 A1
(43) Pub. Date: Dec. 29, 2005

(54) Solar laminates as laminated safety glass

(76) Inventor: Bernhard Koll, St. Augustin (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 11/157,993

(22) Filed: Jun. 22, 2005

(30) Foreign Application Priority Data
Jun. 23, 2004 (DE) 102004030411

(51) Int. Cl. H01L 21/00; H01L 25/00

(52) U.S. Cl. 136/251; 438/64

(57) ABSTRACT

Solar modules, with the properties of laminated safety glass, comprising a laminate containing a) a glass pane b) at least one solar cell unit that is located between two PVB-based films, and
c) a rear covering and at least one of the PVB-based films has a tensile strength of at least 16 N/mm², are suitable for use as a facade component, roof surface, winter garden covering, soundproofing wall, or as a component of windows.

### FIELD OF THE INVENTION

The invention relates to solar modules made as laminated safety glass using a polyvinyl butyral (PVB)-based film, a process for producing the solar modules and their use.

Solar modules generally consist of a photosensitive semiconductor layer (hereinafter called a solar cell unit) and are provided with a transparent covering for protection against external effects. The solar cell units are often laminated between a glass pane and a rigid, rear cover plate, e.g., of glass, using a transparent adhesive. The transparent adhesive must completely surround the solar cell units, must be UV-stable and must be completely free of bubbles after the lamination process.

Since the solar cell units are extremely sensitive to fracture, curing casting resins or crosslinkable ethylene vinyl acetate (EVA)-based systems are often used as transparent adhesives, such as, for example, as disclosed in DE 41 22 721 C1 or DE 41 28 766 A1. These adhesive systems can be set to have low viscosity in the uncured state so that they surround the solar cell units without bubbles. After adding a curing agent or a crosslinking agent, a mechanically resistant adhesive layer is obtained. The disadvantage in these solar modules is their complex manufacture; especially for large-area facade elements, the embedding of the solar cell units into the liquid casting resin and its controlled curing constitute a process that is difficult to control. Moreover, some casting resins after a few years tend to undergo bubble formation or delamination.

One alternative to curing adhesive systems is the use of polyvinyl butyral (PVB)-based films. Here, the solar cell units are embedded between PVB films, and the latter are joined to the desired cover materials to form a laminate under elevated pressure and at elevated temperature. Processes for producing solar modules using PVB-films are known by, e.g., DE 40 26 165 C2, DE 42 27 860 A1, DE 29 23 770 C2, DE 35 38 986 C2 or U.S. Pat. No. 4,321,418. In these publications, the PVB film is used solely for embedding the solar cell units; safety aspects or the properties of the PVB film that are necessary for this purpose are not described.

The use of PVB films in solar modules as laminated safety glazing is disclosed in DE 20 302 045 U1 and DE 35 389 86 C2. These publications, however, do not contain any information about the safety properties of laminated glasses or the properties of the PVB film used.

It is recognized that the safety properties of a laminate of glass and PVB film depend on the adhesive force between the film and glass. The adhesive force should be so high that upon mechanical destruction of the glass, it is ensured that the glass fragments continue to adhere to the film, and sharp-edged glass shards cannot be detached. When the adhesive force of the film is high, an impacting object, however, can penetrate the laminated glass since the PVB film is hardly elastically deformed at the impact site and contributes only a little to deceleration of the object. If the adhesion to the glass is at a lower level, the PVB film at the impact site can detach from the glass and deform as it stretches, by which the impacting object is decelerated.

Since overly low adhesion of the PVB film to the glass facilitates detachment of the glass fragments from the film and thus increases the risk of shattering, in practice a compromise is sought between high and low adhesive force, therefore a medium level of adhesion. This is especially the case in laminated safety glass for motor vehicles, where high penetration inhibition is important. Laminated safety glass panes for construction, especially in roofing, require good binding of shards, so that the PVB film should have relatively high adhesion between the glass and adhesive film.

Solar modules are being increasingly used in buildings as facade elements or roof surfaces. These modules, in addition to good photovoltaic light efficiency, must also have properties that are comparable to laminated safety glazing. The described solar modules have solar cells embedded in PVB film, but they do not have the safety properties of laminated safety glass.

An object of this invention is, therefore, to make available solar modules with the properties of laminated safety glazing using PVB-based films.

### SUMMARY OF THE INVENTION

The safety properties of laminated glazing are determined especially by the intermediate layer film used, here PVB film. In particular, penetration of the glazing should be avoided so that the PVB film must have sufficient tensile strength.

The subject matter of this invention is therefore solar modules as laminated safety glasses, comprising a laminate of
a) a glass pane
b) at least one solar cell unit that is located between two PVB-based films, and
c) a rear covering,
   at least one of the PVB-based films having a tensile strength according to EN ISO 527/3 of at least 16 N/mm².

Furthermore, the subject matter of the invention is a process for producing a solar module as laminated safety glass, by making available a body comprising
a) a glass pane,
b) at least one solar cell unit that is located between two PVB-based films, at least one film having a tensile strength according to EN ISO 527/3 of at least 16 N/mm², and
c) a rear covering,
   by lamination of the body under elevated or reduced pressure and at elevated temperature.

Lamination takes place as the film is fused so that a bubble-free and striation-free bond of the PVB-based films with one another is obtained.

In addition to 50-80% by weight of PVB, 50-20% by weight of softener and small amounts of adhesion regulators, suitable PVB-based films contain antiblocking agents and UV stabilizers. Films of this type are hereinafter called PVB films for short. The fundamental production and composition of PVB films for laminated safety glazing are described in, e.g., EP 0 185 863 B1, EP 1 118 258 B1 or WO 02/102591 A1. The PVB films disclosed here can be adapted to the required tensile strength by the type and/or amount of softener or the type and molecular weight of the PVB resin or its crosslinking.

To produce the solar modules according to the invention with laminated safety properties, it is necessary that at least one of the PVB films of the module have the indicated tensile strength. The other film, preferably the film bordering the rear covering, can have lower strength. Preferably, the two PVB films have the same tensile strength; especially preferably the composition of the two films is identical.

In one special embodiment of this invention, the solar module has sound-insulating properties by at least one, preferably two of the films having soundproofing properties.

Soundproofing films based on PVB are described in, e.g., EP 1 118 258 B1 or EP 0 387 148 B1, the entire disclosures of which are hereby incorporated by reference. Soundproofing films according to EP 1 118 258 B1 increase the sound insulation of a laminated safety glass at its coincidence frequency in the range from 1000 to 3500 Hz by at least 2 dB, measured according to DIN EN ISO 717.

Suitable sound-insulating films according to EP 1 118 258 B1 contain the following:
50 to 80% by weight of PVB (partially acetalized polyvinyl alcohol)
20 to 50% by weight of a softener mixture containng
   30 to 70% by weight—computed as a proportion of the softener mixture—of one or more polyalkylene glycols of the group consisting of
      polyalkylene glycols of general formula HO—(R—O)ₙ—H with R=alkylene and n>5
      derivatives of polyalkylene glycols of general formula R₁—O—(R₂—O)ₙ—H with R₂=alkylene and n≧2, in which the hydrogen of one of the two terminal hydroxy groups of the polyalkylene glycol is linked to an organic radical R₁
      derivatives of polyalkylene glycols of general formula R₁—O—(R₂—O)ₙ—R₃ with R₂=alkylene and n>5, in which the hydrogen of the two terminal hydroxy groups of the polyalkylene glycol is linked to an organic radical R₁ and R₃
   70 to 30% by weight—computed as a proportion of the softener mixture—of one or more standard softeners such as di-n-hexyladipate (DHA) and triethylene glycol-bis-n-heptanoate (3G7).

PVB films that can be used according to the invention preferably have a tensile strength according to EN ISO 527/3 from 16 to 30 N/mm², especially from 16 to 25 N/mm² and preferably from 18 to 23 N/mm².

The PVB films that can be used according to the invention must surround the solar cell units and their electrical terminals without bubbles and actuated by adhesion; at the same time, a total thickness of the solar modules that is as small as possible is required. To this end, it is feasible that under the production conditions, at least one PVB film “makes way for” the inserted solar cell units, i.e., has a certain flow capacity under lamination conditions.

Softer, i.e., flowable films, of course, have lower tensile strength, but are simpler to process. To obtain the desired safety properties, sufficient tensile strength must be considered.

Suitable PVB films therefore preferably have one of the following melt flow indices according to DIN 53735 (with 2 mm nozzles):

| Load/temperature | Melt flow index [g/10 min] |
|---|---|
| 2.16 kg/150° C. | 15 to 40, preferably 20 to 35 |
| 2.16 kg/120° C. | 0.5 to 5, preferably 1 to 4 |
| 2.16 kg/100° C. | 0.1 to 1, preferably 0.2 to 0.6 |

PVB films with the indicated melt flow indices during the lamination process fill the cavities that are present on the solar cell units or their electrical connections.

Furthermore, the PVB films fuse to one another without bubbles and seams, so that an optically perfect product is obtained.

In addition to tensile strength, the adhesion of the PVB films to the glass and to the solar cell units is important. The degree of fragment binding of PVB film in laminated safety glass is determined by the so-called Pummel test. The execution of this test is known to one skilled in the art and is described in WO 03/033583 A1. Depending on use, the solar modules according to the invention should have Pummel values from 3 to 6 (higher penetration protection) or 7 to 10 (good fragment binding in, e.g., overhead glazing). Preferably, a compromise of these properties is sought with Pummel values from 6 to 8.

The adhesion capacity of PVB films to glass can be adjusted by the addition of adhesion regulators, such as, e.g., alkali salts and/or alkaline-earth salts of organic acids that are disclosed in WO 03/033583 A1. Potassium acetate and/or magnesium acetate have been found to be especially well suited. To obtain high Pummel values, it can be necessary to use PVB films without adding adhesion regulators such as alkali salts and/or alkaline-earth salts.

Furthermore, the safety properties of the solar modules according to the invention are determined by the adhesion properties of the PVB films to glass. The latter can be described by measuring the compression shear adhesion.

When measuring the film adhesion to glass surfaces, the different surface properties of fiat glass must be considered. In the production of flat glass, one side of the glass is facing a tin bath and the other side is facing the air; this results in tin doping of the bath side. The different sides of flat glass due to the doping have different adhesion of the PVB film.

Therefore, the adhesion properties of PVB films in glass laminates are conventionally measured by the film's having contact with the same sides of the glass panes. The data on compression shear adhesion on air/air and tin/tin glass surfaces relate to laminates with the corresponding structure.

The determination of compression shear adhesion is done according to the methods that are described in more detail below and that are named in a way similar to EP 0 067 022 and DE 197 56 274 A1. The other measurements are taken using the cited standards. All tests are run on glass/glass laminates with a structure identical to the solar modules according to the invention, but without the solar cells.

PVB films that are suitable for use in the solar modules according to the invention preferably have compression shear adhesion on air/air glass surfaces of 10-30 N/mm², preferably 15-25 N/mm² and especially 15-20 N/mm².

The compression shear adhesion of these films to glass surfaces with respect to the tin/tin sides of the glass is preferably 10-25 N/mm², more preferably 15-20 N/mm².

Solar modules according to the invention are equipped with a front glass panel and/or a rear glass pane, e.g., of float glass or completely or partially tempered glass, each preferably with a thickness of between 3 and 10 mm. The thickness of the PVB films is 0.38, 0.51, 0.76, 1.14 and/or 1.52 mm.

### BRIEF DESCRIPTION OF THE DRAWINGS

Various other features and attendant advantages of the present invention will be more fully appreciated as the same becomes better understood when considered in conjunction with the accompanying drawings, wherein:

FIG. 1 illustrates a solar module according to the invention; and

FIG. 2 illustrates a solar module according to the invention containing several solar cell units.

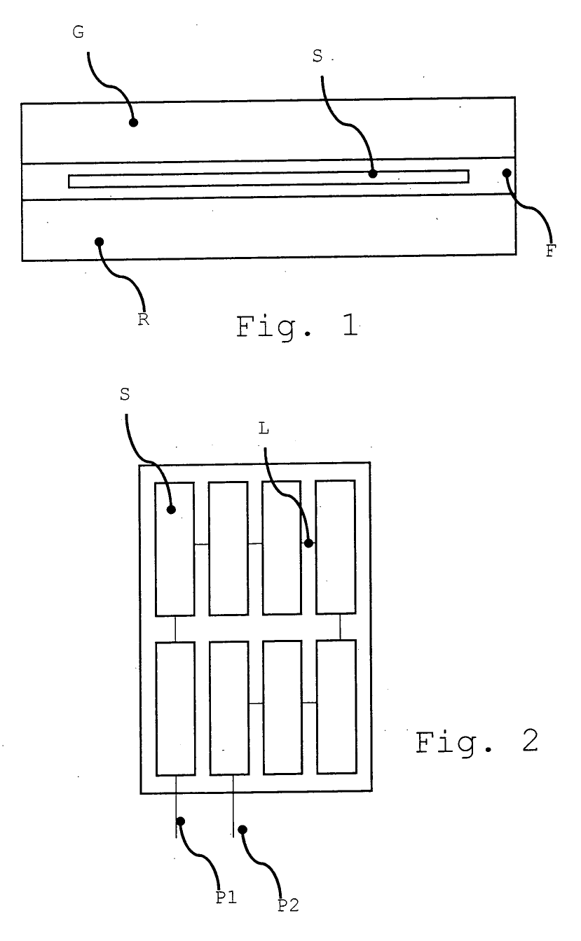

FIG. 1 outlines the structure of a solar module according to the invention. Here, G stands for the glass pane (front) and R stands for the rear covering. Solar cells S are encapsulated by PVB films F that have been fused to one another.

It is possible to make the front glass pane as laminated safety glass, i.e., as a laminate of at least two glass panes and at least one PVB film, to increase the safety.

The rear covering of the solar modules can consist of glass, plastic or metal. It is likewise possible to make such a covering of glass as laminated glazing or as insulating glazing with an intermediate gas space. Of course, the combination of these measures is also possible.

The solar cells that are used in the solar modules need not have any special properties. Monocrystalline, polycrystalline or amorphous systems can be used. The thickness of the crystalline solar cells is preferably 0.1 to 0.5 mm. In order to deliver sufficient voltage, the solar cells are electrically connected to one another in units of 5 to 20 cells.

In order to increase the fracture safety of the solar modules according to the invention, the electrical connections of the solar units to one another or the current delivery of the solar units from the solar module are not routed through holes through the front and rear. More feasibly, the required conductor paths like the solar cells themselves are placed between the PVB films and thus routed out of the solar module. FIG. 2 shows one such structure, S standing for the solar cell units, L for the conductor paths between the solar cell units and P1 and P2 for the current delivery leads.

The process according to the invention for producing the solar modules is preferably carried out such that a PVB film is placed on the rear covering of the solar module, and in turn the solar cell units with the connecting conductor paths are located on this film. Then, the second PVB film is applied in some manner, and the front glass pane is put into place. The layered body that has been prepared in this way is finally processed into a laminate under elevated or reduced pressure and at elevated temperature.

To laminate the layered body that has been obtained in this way, processes that are familiar to one skilled in the art can be used with and without prior production of a prelaminate.

So-called autoclave processes are carried out at an elevated pressure from roughly 10 to 15 bar and temperatures from 130 to 145° C. over roughly 2 hours. Vacuum bag processes or vacuum ring processes, e.g., according to EP 1 235 683 B1, work at roughly 200 mbar and 130 to 145° C.

Preferably, vacuum laminators are used to produce the solar modules according to the invention. The latter consist of a heatable chamber that can be evacuated, in which laminated glazing can be laminated within 30-60 minutes. Reduced pressures from 0.01 to 300 mbar and temperatures from 100 to 200° C., especially 130-160° C., have proven effective in practice.

Solar modules according to the invention can be used as facade components, roof surfaces, a winter garden covering, a soundproofing wall, balcony or parapet element or as a component of window surfaces.

In the foregoing and in the following examples, all temperatures are set forth uncorrected in degrees Celsius; and, unless otherwise indicated, all parts and percentages are by weight.

The entire disclosure of all applications, patents and publications, cited above and below, and of corresponding German Application No. 102004030411, filed Jun. 23, 2004, is hereby incorporated by reference.

Compression Shear Test

To assess the adhesion of a PVB film, the compression shear test based on DE 197 56 274 A1 is run on a glass/glass laminate without solar cells. To produce the test piece, the PVB film to be tested is placed between two flat silicate glass panes with a 300 mm×300 mm format with a thickness of 2 mm. It is degassed in a prelaminate furnace with calender rolls into a glass prelaminate, and is then pressed in an autoclave at a pressure of 12 bar and at a temperature of 140° C. within a total of 90 minutes into a flat laminated safety glass. Ten samples with dimensions of 25.4 mm×25.4 mm are cut out of the laminated safety glass that has been produced in this way. The latter are clamped at an angle of 45° in a test apparatus according to DE 197 56 274 A1, the thickness of the recesses being roughly ⅔ of the respective glass thickness. The upper half is exposed to a steadily increasing force that is pointed exactly vertically down until shearing-off occurs within the test piece, i.e., the laminated safety glass panes to be tested.

The test parameters are as follows:

| | |
|---|---|
| Test piece: | Square 25.4 mm × 25.4 mm |
| Placement: | Bottom pane each with air or fire side toward |
| | the film (air/air), or top and bottom pane each |
| | with tin side toward the film (bath/bath) |
| Storage prior | 4 hours under normal conditions 23° C./50% |
| to the test: | rel.hum. |
| Feed rate: | 2.5 mm/min |
| No. of samples: | 10 |
| Evaluation: | Maximum force that is required for shearing |
| | the film off the glass. The force is related to |
| | the sample surface area (in N/mm² or psi) |

For each test piece, the force applied in shearing-off is averaged from ten identical test pieces in a linear manner. To the extent reference is made to the average compression shear test value in the following examples and claims, the average value from 10 measurements is intended. Otherwise reference is made to DE 197 56 274 A1.

### EXAMPLES

Laminated glass panes that consist of two glass panes (float glass) and two films with interposed solar cells were produced by production of a prelaminate by means of a vacuum process at about 130-140° C. and subsequent autoclave processes. As films, commercially available ethylene vinyl acetate film (EVA) that is suitable for embedding solar cells and the PVB film according to the invention were used. The autoclave process for EVA films was performed at 130° C., 30 minutes of holding time, 9 bar, and the autoclave process for the PVB film according to the invention was performed at 140° C., 30 minutes of holding time, 12 bar.

The laminated glazings were bubble-free and transparent after the autoclave process; the solar cells were completely encased by polymer film.

The following laminated glazings (dimensions 900×1100 mm) were subjected to a screen test according to DIN EN 356:

### Comparison Example 1

| | |
|---|---|
| Material: | 4 mm glass, 3*0.4 mm EVASAFE (Bridgestone Company) |
| 1^{st} Ball: | Pane broken. |
| 2^{nd} Ball: | Wide crack. |
| 3^{rd} Ball: | Ball falls through smoothly. |
| Test Result: | Test Class P2A not passed. |

### Comparison Example 2

| | |
|---|---|
| Material: | 4 mm glass, 2*0.5 mm commercially available solar-EVA |
| | film |
| 1^{st} Ball: | Pane broken. |
| 2^{nd} Ball: | Ball falls through. |
| Test Result: | Test Class P1A not passed. |

### Example 1

| | |
|---|---|
| Material: | 4 mm glass, 2*0.5 mm PVB film according to the invention |
| 1^{st}-3^{rd} Balls: | No crack. |
| Test Result: | P1A safely passed. |

### Example 2

| | |
|---|---|
| Material: | 4 mm glass, 2*0.5 mm PVB film according to the invention |
| 1^{st} Ball: | Pane broken. |
| 2^{nd} Ball: | Wide crack. |
| 3^{rd} Ball: | Held. |
| Test Result: | P2A passed. |

It was shown that the solar modules that are produced with the PVB film according to the invention have, in addition to a transparent structure and securely coated solar cells, the screen-inhibiting action of laminated safety glass of test classes P1A and P2A of DIN EN 356. These safety classes are not satisfied by analogous laminated glazings with EVA film.

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

1. A laminated safety glass solar module comprising a laminate of
a) a glass pane
b) at least one solar cell unit that is located between two PVB-based films, and
c) a rear covering, wherein at least one of the PVB-based films has a tensile strength of at least 16 N/mm².

2. A solar module according to claim 1, wherein at least one of the PVB-based films has a melt flow index of 15 to 40 g/10 minutes, measured at a load of 2.16 kg and at 150° C.

3. A solar module according to claim 1, wherein at least one of the PVB-based films in a glass/glass laminate has compression shear adhesion on air/air glass surfaces of 10 to 30 N/mm².

4. A solar module according to claim 1, wherein at least one of the PVB-based films in a glass/glass laminate has compression shear adhesion on tin/tin glass surfaces of 10 to 25 N/mm².

5. A solar module according to claim 1, wherein the rear covering is made from glass, plastic, metal, laminated glazing and/or insulating glazing.

6. A solar module according to claim 1, wherein at least one of the two PVB-based films has soundproofing properties.

7. A solar module according to claim 1, wherein current is delivered to the solar cell units via conductor paths placed between the PVB-based films.

8. A process for producing a solar module in the form of a laminated safety glass, comprising:
making a body of
a) a glass pane as the front side,
b) at least one solar cell unit that is located between two PVB-based films, at least one film having a tensile strength of at least 16 N/mm², and
c) a rear covering,
by lamination of the body under elevated or reduced pressure and at elevated temperature.

9. A process according to claim 8, wherein lamination is carried out at a reduced pressure of 0.01 to 300 mbar and at a temperature of 100 to 200° C.

10. In a facade component, roof surface, winter garden covering, soundproofing wall, balcony or parapet element or as a component of windows comprising at least one solar module, the improvement wherein said solar module is a module according to claim 1.
